(19) United States
(12) Patent Application Publication
(10) Pub. No.: US 2026/0094793 A1
(43) Pub. Date: Apr. 2, 2026

(54) SUBSTRATE PROCESSING APPARATUS

(71) Applicant: Samsung Electronics Co., Ltd., Suwon-si (KR)

(72) Inventors: Tae-Hyun Kim, Suwon-si (KR); Chansoo Kang, Suwon-si (KR); Kyunghyun Kim, Suwon-si (KR); Sang Ki Nam, Suwon-si (KR); Jitae Park, Suwon-si (KR); Jin Young Bang, Suwon-si (KR); Dougyong Sung, Suwon-si (KR); Sejin Oh, Suwon-si (KR); Sungho Jang, Suwon-si (KR)

(21) Appl. No.: 19/180,671

(22) Filed: Apr. 16, 2025

(30) Foreign Application Priority Data
Sep. 30, 2024 (KR) 10-2024-0133302

(51) Int. Cl. H01J 37/32

(52) U.S. Cl. CPC H01J 37/32935; H01J 37/32458; H01J 2237/221; H01J 2237/24507

(57) ABSTRACT

A substrate processing apparatus according to an embodiment includes: a chamber including a measurement window in a side of the chamber and configured to provide a path for light to propagate; a plasma excitation member configured to apply energy for excitation of plasma in the chamber; a support member inside of the chamber and configured to support a substrate; and a detection module positioned to face the measurement window, and configured to detect light emitted from the plasma excitation member through the window.

### CROSS-REFERENCE TO RELATED APPLICATION

This application claims priority to and the benefit of Korean Patent Application No. 10-2024-0133302, filed on Sep. 30, 2024, in the Korean Intellectual Property Office, the entire contents of which are incorporated herein by reference.

### FIELD

The present disclosure relates to a substrate processing apparatus.

### BACKGROUND

When manufacturing a semiconductor device, various processes such as photolithography, etching, ashing, ion implantation, thin film deposition, and cleaning, and the like are performed on a substrate to form a desired pattern. Among these, the etching process is a process of removing a selected heating region from a film formed on the substrate, and wet etching and dry etching are used.

An etching apparatus using plasma is used for dry etching. In general, for generating plasma, an electric field is formed in an internal space of a chamber, and the electric field excites process gases provided in the chamber into a plasma state.

Plasma refers to an ionized gas state composed of ions, electrons, and radicals. Plasma is generated by very high temperatures, strong electric fields, or high-frequency electromagnetic fields (RF electromagnetic fields). In a semiconductor device manufacturing process, the etching process is performed using plasma. The etching process is performed by collision of ion particles contained in the plasma with the substrate.

### SUMMARY

The present disclosure attempts to provide a substrate processing apparatus capable of efficiently processing a substrate using plasma while monitoring a state of process.

However, the purpose that the embodiments of the present disclosure seek to solve is not limited to the purpose described above and may be expanded in various ways within a scope of technical concept included in the present disclosure.

A substrate processing apparatus according to an aspect may include: a chamber including a measurement window in a side of the chamber and configured to provide a path for light to propagate; a plasma excitation member configured to apply energy for excitation of plasma in the chamber; a support member inside of the chamber and configured to support a substrate; and a detection module positioned to face the measurement window, and configured to detect light emitted from the plasma excitation member through the measurement window.

A substrate processing apparatus according to another aspect may include: a chamber including a measurement window in a side of the chamber and configured to provide a path for light to propagate; a plasma excitation member configured to apply energy for excitation of plasma; a support member inside of the chamber and configured to support a substrate; and a detection module positioned to face the measurement window, and configured to detect light emitted from the substrate positioned on the support member through the measurement window when the substrate is processed.

A substrate processing apparatus according to another aspect may include: a chamber including a measurement window in a side of the chamber and configured to provide a path for light to propagate; a plasma excitation member configured to apply energy for excitation of plasma in the chamber; a support member inside of the chamber and configured to support the substrate; and a detection module positioned to face the measurement window, and configured to detect light emitted from the plasma excitation member through the measurement window, wherein the detection module includes: a photosensitive sensor; a lens configured to refract incident light to propagate the incident light toward the photosensitive sensor; and a wavelength filter between the photosensitive sensor and the lens and configured to filter a wavelength band whose intensity exhibits a peak value in a wavelength spectrum of bulk plasma excited inside the chamber.

According to some embodiments, a substrate processing apparatus capable of efficiently processing a substrate through plasma while monitoring a process status can be provided.

### BRIEF DESCRIPTION OF THE DRAWINGS

FIG. 1 is a drawing illustrating a substrate processing apparatus according to some embodiments.

FIG. 2 is a cross-sectional view along line A-A′ of FIG. 1.

FIG. 3 is a drawing illustrating a detection module of the substrate processing apparatus of FIG. 1.

FIG. 4 is a drawing illustrating a control relationship of a substrate processing apparatus according to some embodiments.

FIG. 5 is a drawing illustrating light incident to a detection module through the measurement window of a substrate processing apparatus according to some embodiments.

FIG. 6 is a drawing illustrating a wavelength spectrum of light emitted from bulk plasma.

FIG. 7 is a drawing illustrating a wavelength spectrum of light emitted by cathodoluminescence.

FIG. 8 is a drawing illustrating a state of a polarization filter wherein light oscillating in a direction and incident through the measurement window is filtered by the polarization filter according to some embodiments.

FIG. 9 is a drawing illustrating a state of a polarization filter wherein light oscillating in a direction and incident through the measurement window passes through the polarization filter according to some embodiments.

FIG. 10 and FIG. 11 are drawings illustrating a process of converting a measurement image measured by a detection module into a compensated image representing light emitted from the lower surface of a plasma excitation member according to some embodiments.

FIG. 12 is a drawing illustrating a detection module according to some embodiments.

FIG. 13 is a drawing illustrating a substrate processing apparatus according to some embodiments.

FIG. 14 is a drawing illustrating a substrate processing apparatus according to some embodiments.

### DETAILED DESCRIPTION

Hereinafter, with reference to accompanying drawings, embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. Additionally, in the drawings, for convenience of explanation, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Throughout the specification, when referring to a first surface of a first component which is “configured to face” or which “faces” a second component or a second surface, it should be understood that it means that the direction (or vector) which is normal to the first surface is substantially the direction in which the second component or second surface is located relative to the first surface. Similarly, when referring to a first component which is “configured to face” or which “faces” a second component, it should be understood that it means that the first component has an active surface, side, or end and that the direction (or vector) which is normal to the active surface, side, or end is substantially the direction in which the second component is located relative to the first component.

In addition, throughout the specification, when referring to “a plane view”, it means that the target portion is viewed from above, and when referring to “a cross-section view”, it means that a cross section of the target portion cut vertically is viewed from a side.

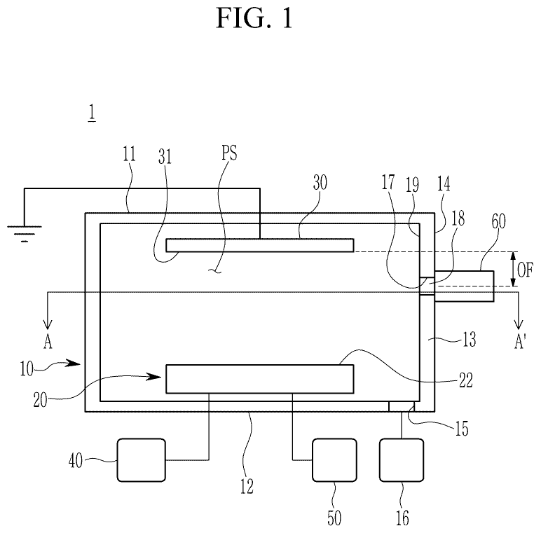

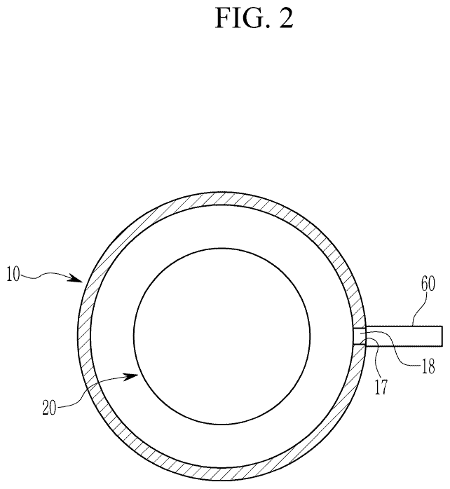

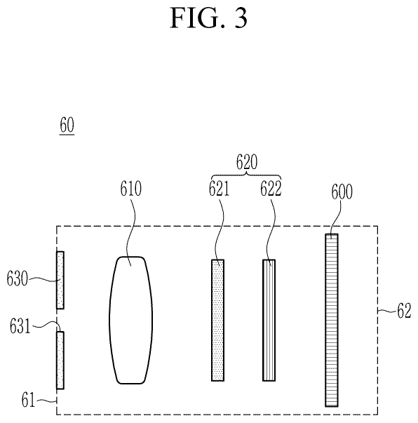

FIG. 1 is a drawing illustrating a substrate processing apparatus according to some embodiments. FIG. 2 is a cross-sectional view along line A-A′ of FIG. 1. FIG. 3 is a drawing illustrating a detection module of the substrate processing apparatus of FIG. 1.

Referring to FIG. 1 through FIG. 3, a substrate processing apparatus 1 according to some embodiments may include a chamber 10, a support member 20, a plasma excitation member 30, an excitation supply unit 40, a bias supply unit 50, and a detection module 60.

The substrate processing apparatus 1 processes a substrate. The substrate processing apparatus 1 may process a substrate using plasma. For example, the substrate processing apparatus 1 may perform an etching process using excited plasma. The substrate may be a wafer for manufacturing a semiconductor device.

The chamber 10 provides a processing space PS inside of which the substrate processing is performed. The chamber 10 has processing space PS inside and may be provided in a closed and sealed shape. The chamber 10 may be made of metallic material. For example, the chamber 10 may be made of aluminum material, etc. The chamber 10 may be grounded.

An exhaust hole 15 may be positioned in a side of the chamber 10. In other words, the chamber 10 may include an exhaust hole 15 which may penetrate through a side wall 13, 14, upper wall 11, or lower wall 12 of the chamber 10. The exhaust hole 15 may be positioned in a lower region of the chamber 10. For example, the exhaust hole 15 may be positioned in a lower wall 12 of the chamber 10. Reaction byproducts generated during processing and gases remaining in the internal space of the chamber 10 may be discharged to outside through the exhaust hole 15. The inside of the chamber 10 may be depressurized to a predetermined pressure by a discharging process. The discharge member 16 may be connected to the exhaust hole 15. The discharge member 16 applies negative pressure inside of the chamber 10 for exhaust. Additionally, the discharge member 16 may control the flow rate of gas discharged through the exhaust hole 15. The discharge member 16 may include at least one or more pumps. For example, the discharge member 16 may include a turbo molecular pump. In addition, the discharge member 16 may include a valve, so that the flow rate of gas discharged through the exhaust hole 15 may be controlled according to degree of opening and closing the valve.

The measurement window 17 may be positioned in a side of the chamber 10. The measurement window 17 may penetrate a inner surface of the chamber 10 and a outer surface of the chamber 10, so that the measurement window 17 may provide a path for light generated inside the chamber 10 to propagate to the outside of the chamber 10. In some embodiments, the measurement window 17 may be positioned in a side wall 13 of the chamber 10. The side wall 13 may be positioned between the upper wall 11 of the chamber 10 and the lower wall 12 of the chamber 10. In other words, the chamber 10 may include a measurement window 17 which may penetrate or extend through a side wall 13, 14, upper wall 11, or lower wall 12 of the chamber 10.

A shield member 18 may be inside of or adjacent to the measurement window 17 to shield the inside of the chamber 10 from the outside of the chamber 10. The shield member 18 may be transparent or semi-transparent. For example, the shield member 18 may be made of glass, quartz, fused silica, etc. FIG. 1 and FIG. 2 illustrate an example where the shield member 18 is positioned in the measurement window 17 and has a thickness substantially equal to the thickness of the side wall 13 of the chamber 10. However, the shield member 18 may have a thickness smaller than that of the side wall 13 of the chamber 10 and may be positioned only in a section of the measurement window 17.

The support member 20 is inside the chamber 10. The support member 20 may be in a lower portion of the processing space PS. The support member 20 supports the substrate. The support member 20 may fix the substrate using electrostatic force. The support member 20 may include a plurality of components. The support member 20 may include an electrostatic chuck and a focus ring.

The electrostatic chuck may be in an upper portion of support member 20. Accordingly, the substrate may be positioned on an upper surface of the electrostatic chuck. The upper surface of the electrostatic chuck may be made of a dielectric material. The electrostatic chuck may fix the substrate by electrostatic force. The focus ring may be in an outer region of the upper portion of the support member 20. The focus ring may be in an outer circumference of the upper portion of the electrostatic chuck. The focus ring may control the state of a plasma sheath in an outer edge region of the upper surface of the electrostatic chuck.

A refrigerant flow path may be formed inside the support member 20. The refrigerant flow path provides a path for the refrigerant to flow in the support member 20. For example, the refrigerant flow path may be formed in a spiral shape. Additionally, in the refrigerant flow path, ring-shaped flow paths having different radii may be arranged with a same center. In this case, the refrigerant flow path may be configured so that ring-shaped flow paths communicate with each other. Refrigerant circulates through the refrigerant flow path and chills the support member 20. The support member 20, as being cooled, chills the substrate positioned on the support member 20.

At least some regions of the support member 20 may made of conductive material. For example, at least some regions of the support member 20 may be made of metal material. Accordingly, the support member 20 may function as an electrode.

In support member 20, a region made of conductive material may be positioned below a region made of dielectric material. In the support member 20, the region made of conductive material may be positioned below the electrostatic chuck. In the support member 20, the region made of conductive material may be positioned in the inner region of the support member 20. Accordingly, in support member 20, the region made of conductive material may be prevented from being exposed to plasma during processing.

The plasma excitation member 30 applies energy for plasma excitation to the processing space PS. A lower surface 31 of the plasma excitation member 30 may be positioned to face the inside of the chamber 10. The plasma excitation member 30 may be inside the chamber 10. For example, the plasma excitation member 30 may be manufactured separately from the chamber 10 and connected to the chamber 10. Alternatively, the plasma excitation member 30 may be provided integrally with the upper structure of the chamber 10. In other words, the upper structure of the chamber 10 may function as plasma excitation member 30.

The plasma excitation member 30 may be in an upper portion of the processing space PS. The plasma excitation member 30 may be made of conductive material and have a predetermined area. The plasma excitation member 30 may be configured to face the support member 20 in a vertical direction. The lower surface 31 of plasma excitation member 30 may be positioned to face the upper surface 22 of support member 20 in the vertical direction.

The excitation supply unit 40 provides electric power for plasma excitation. The excitation supply unit 40 may be electrically connected to support member 20. The excitation supply unit 40 may be electrically connected to the region made of conductive material in the support member 20. The excitation supply unit 40 may include a high-frequency power source generating high-frequency electric power. The excitation supply unit 40 may include a RF power.

The bias supply unit 50 is electrically connected to the support member 20 and provides electric power for bias. The bias supply unit 50 may be electrically connected to the region made of conductive material in the support member 20. In a region adjacent to the upper surface 22 of the support member 20, the state of a plasma sheath, the state of plasma concentration to the substrate, and the state of ion incidence to the substrate may be controlled by the electric power supplied by the bias supply unit 50. The bias supply unit 50 may include a voltage source to output a voltage.

The process gas inserted into the chamber 10 may be excited into plasma by the electric field generated inside the chamber 10. Specifically, the process gas may be excited into plasma by a capacitively coupled plasma (CCP) source. The capacitively coupled plasma source may include an upper electrode and a lower electrode. The upper electrode and the lower electrode may be arranged to vertically face each other inside the chamber 10. By applying high-frequency electric power to at least one of the upper and lower electrodes, an electric field is generated in the space between the upper electrode and the lower electrode, and the process gas supplied into this space may be excited into plasma state. The upper electrode may be the plasma excitation member 30, and the lower electrode may be the support member 20. High-frequency power source may be connected to only one of the upper and lower electrodes. For example, the upper electrode may be grounded, and the high-frequency power source may be connected only to the lower electrode. Alternatively, the lower electrode is grounded, and the high-frequency power source may be connected only to the upper electrode. Additionally, high frequency power source may be connected to both the upper electrode and lower electrode. FIG. 1 illustrates an example where a high-frequency power source is connected to the lower electrode.

The detection module 60 may detect light emitted inside the chamber 10. The detection module 60 may detect light emitted from the plasma excitation member 30. The detection module 60 may detect light emitted from the lower surface 31 of the plasma excitation member 30.

The detection module 60 is configured to face the measurement window 17 and may detect light incident through the measurement window 17.

The detection module 60 may be spaced downwardly apart from the lower surface 31 of the plasma excitation member 30 by an offset distance OF. In other words, a center line of the detection module 60 may be an offset distance OF in a vertical direction from the lower surface 31 of the plasma excitation member 30. The offset distance OF has a value greater than 0. Additionally, the offset distance OF may be 5 mm or more. The offset distance OF may be 10 mm or more. Accordingly, light emitted from the lower side of the plasma excitation member 30 may propagate in a direction oblique to vertical direction and horizontal direction and may enter the detection module 60.

The detection module 60 may be outside the processing space PS. As an example, the detection module 60 may be connected to a region, where a measurement window 17 is positioned, of the outer surface 14 of the side wall 13 of the chamber 10. Additionally, at least a portion of the detection module 60 may be inserted inside the measurement window 17. In other words, at least a portion of the detection module 60 may be inserted at the outer surface 14 of the side wall 13 of the chamber 10 toward the inner surface 19 of the side wall 13 of the chamber 10. Also, the detection module 60 may be apart from the outer surface 14 of the side wall 13 of the chamber 10 to face the measurement window 17. FIG. 1 and FIG. 2 illustrate an example where the detection module 60 is connected to the side wall 13 of the chamber 10.

The detection module 60 may include a photosensitive sensor 600, a lens 610, and a filter 620.

In the following descriptions, ‘front side’ (or ‘in front of’) and ‘rear side’ (or ‘behind’) are set in reference to the propagation direction of light incident into the detection module 60 inside the chamber 10. In other words, light incident into the detection module 60 may propagate from ‘front side’ to ‘rear side’ inside the chamber 10. Accordingly, in the detection module 60, a side toward the measurement window 17 is the front side 61, and a side toward the opposite of the measurement window 17 is the rear side 62. In other words, the front side 61 is the side of the detection module 60 that is closest to the measurement window 17 and the rear side 62 is the side of the detection module 60 farthest from the measurement window 17.

The photosensitive sensor 600 may detect light. The photosensitive sensor 600 may detect light emitted inside the chamber 10. For example, the photosensitive sensor 600 may include a charge coupled device (CCD) sensor, a complementary metal oxidation semiconductor (CMOS) sensor, etc. Additionally, the photosensitive sensor 600 may include a photomultiplier, a photodiode, an optical fiber sensor, etc. Additionally, the photosensitive sensor 600 may include an array of photomultipliers, an array of photodiodes, an array of optical fiber sensors, etc.

The lens 610 may be on the path of light generated inside the chamber 10 and passing through the measurement window 17. The lens 610 may refract the incident light and direct it toward the photosensitive sensor 600. The lens 610 may be spaced downwardly apart from the lower surface 31 of the plasma excitation member 30 by an offset distance OF. A center of the lens 610 may be spaced downwardly apart from the lower surface 31 of plasma excitation member 30 by an offset distance OF. The offset distance OF may have a value greater than 0. The offset distance OF may be 5 mm or more. Additionally, the offset distance OF may be 10 mm or more. Accordingly, light emitted from the lower surface 31 of plasma excitation member 30 may propagate in a direction oblique to vertical direction and horizontal direction and may enter the lens 610.

The lens 610 may be in front of the photosensitive sensor 600, in reference to the propagation path of light. The lens 610 may be between the photosensitive sensor 600 and the internal space of the chamber 10. The lens 610 may be behind the shield member 18. The lens 610 may be between the shield member 18 and the photosensitive sensor 600.

For example, the lens 610 may be behind the outer surface 14 of the side wall 13 of the chamber 10. That is, the lens 610 may be outside the chamber 10. Additionally, at least a portion of the detection module 60 may be inserted into the measurement window 17 from the outer surface 14 of the side wall 13 of the chamber 10 toward the inner surface 19 of the side wall 13 of the chamber 10. Additionally, the lens 610 may be inserted into the measurement window 17 and positioned in a section between the inner surface 19 of the side wall 13 of the chamber 10 and the outer surface 14 of the side wall 13 of the chamber 10.

The lens 610 may control the propagation direction of light incident from the front side 61 which directs the inside of the chamber 10. For example, the light incident from the front may become a parallel beam after passing through the lens 610.

An entrance plate 630 can be in front of lens 610. The entrance plate 630 may be behind the shield member 18. The entrance plate 630 may be between the processing space PS and the lens 610. The entrance plate 630 may be between the shield member 18 and the lens 610. The entrance plate 630 may be opposite to the photosensitive sensor 600, in reference to the lens 610.

A pin hole 631 may be positioned on the entrance plate 630. The pin hole 631 is positioned on the path of light passing through the measurement window 17. That is, the pin hole 631 may be positioned in front of the lens 610. The pin hole 631 may be positioned behind the shield member 18. The pin hole 631 may be positioned between the processing space PS and the lens 610. The pin hole 631 may be positioned between the shield member 18 and the lens 610. The pin hole 631 may be positioned opposite to the photosensitive sensor 600, in reference to the lens 610. For example, the entrance plate 630 may be behind the outer surface 14 of the side wall 13 of the chamber 10. That is, the entrance plate 630 may be outside the chamber 10. Also, at least a portion of the detection module 60 may be inserted at the outer surface 14 of the side wall 13 of the chamber 10 toward the inner surface 19 of the side wall 13 of the chamber 10. Additionally, the entrance plate 630 may be inserted into the measurement window 17 and positioned in a section between the inner surface 19 of the side wall 13 of the chamber 10 and the outer surface 14 of the side wall 13 of the chamber 10. At this time, the entrance plate 630 may be provided as a component separate from the chamber 10 and may be attached to the chamber 10. Additionally, the entrance plate 630 may be provided integrally with the chamber 10. The pin hole 631 may determine a co-relationship between the position information of a region desired to measure through the detection module 60 and the incident angle incident into the lens 610. Additionally, the intensity of the light may be controlled by the size of the pin hole 631.

The filter 620 may be on the path of light passing through the measurement window 17. The filter 620 may be behind the lens 610, in reference to the propagation path of light. The filter 620 may be in front of the photosensitive sensor 600, in reference to the propagation path of light. The filter 620 may be between the photosensitive sensor 600 and the lens 610. Accordingly, light generated inside the chamber 10 may incident to the filter 620 after passing through the lens 610.

The filter 620 may perform filtering on the incident light to improve the efficiency of the measurement by the detection module 60. Then, light passing through the filter 620 may be incident to the photosensitive sensor 600.

The filter 620 may include a wavelength filter 621 and a polarization filter 622.

The wavelength filter 621 may perform filtering on a predetermined wavelength band. That is, when light is incident, the wavelength filter 621 performs filtering out wavelengths in the filtering band and may allow wavelengths other than the filtering band to be transmitted.

The wavelength filter 621 may be behind the lens 610, in reference to the propagation path of light. The wavelength filter 621 may be in front of the photosensitive sensor 600, in reference to the propagation path of light. The wavelength filter 621 may be between the photosensitive sensor 600 and the lens 610. Accordingly, the light generated inside the chamber 10 may be incident to the wavelength filter 621 after passing through the lens 610. Then, light passing through wavelength filter 621 may be incident to the photosensitive sensor 600.

The polarization filter 622 may be transmissive to light oscillation in a predetermined direction. In other words, the polarization filter 622 may transmit light oscillating in a direction parallel to a transmissive axis and perform filtering out light oscillating in other directions.

The polarization filter 622 may be behind the lens 610, in reference to the propagation path of light. The polarization filter 622 may be in front of the photosensitive sensor 600, in reference to the propagation path of light. The polarization filter 622 may be between the photosensitive sensor 600 and the lens 610. Accordingly, light generated inside the chamber 10 may be incident to the polarization filter 622 after passing through the lens 610. Then, light passing through the polarization filter 622 may be incident to the photosensitive sensor 600.

The polarization filter 622 may be in front of a wavelength filter 621, in reference to the propagation direction of light. That is, the polarization filter 622 may be between the wavelength filter 621 and the lens 610. The wavelength filter 621 may be between the polarization filter 622 and the photosensitive sensor 600. Alternatively, the polarization filter 622 may be behind the wavelength filter 621, in reference to the propagation direction of light. In other words, the polarization filter 622 may be between the wavelength filter 621 and the photosensitive sensor 600. Additionally, the wavelength filter 621 may be between the polarization filter 622 and the lens 610. FIG. 3 illustrates an example where the polarization filter 622 is between the wavelength filter 621 and the photosensitive sensor 600.

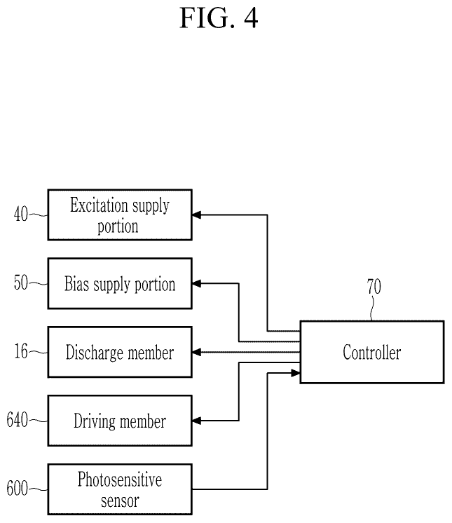

A driving member (640 in FIG. 4) may be connected to the polarization filter 622. The driving member 640 may rotate the polarization filter 622. Since the transmissive axis is rotated according to the rotation of polarization filter 622, the oscillating direction of light that can pass through polarization filter 622 may be changed.

FIG. 4 is a drawing illustrating a control relationship of a substrate processing apparatus 1 according to some embodiments.

Referring to FIG. 4, the controller 70 may control components of the substrate processing apparatus 1.

The controller 70 may control the operation status of the excitation supply unit 40. The controller 70 controls the on/off state of the excitation supply unit 40, and thereby may control the on/off state of supplying energy for plasma excitation inside the chamber 10. For example, the controller 70 may be provided with a stored recipe and may control the excitation supply unit 40 to an on state or an off state according to the stored recipe data.

The controller 70 may control the operation status of the bias supply unit 50. The controller 70 controls the on/off state of the bias supply unit 50, and thereby may control the on/off state of the plasma sheath on the support member 20. The controller 70 controls the bias supply unit 50 to an on state or an off state according to the stored recipe data, and thereby may control the plasma sheath state on the support member 20.

The controller 70 may control the operation status of the discharge member 16. The controller 70 controls the on/off state of the discharge member 16, and thereby may cause exhaust inside the chamber 10 to occur or stop. The controller 70 may control the on/off status of the discharge member 16 according to the stored recipe data. Additionally, the controller 70 may control the exhaust amount per unit time inside the chamber 10 through the discharge member 16. Additionally, the controller 70 may control the pressure state inside the chamber 10 through discharge member 16.

The controller 70 may control the operation status of the detection module 60. The controller 70 may detect light emitted inside the chamber 10 through the detection module 60. The controller 70 may detect the state of plasma inside the chamber 10 through light measured by the detection module 60.

The controller 70 may control the operation status of the driving member 640. The controller 70 may rotate the polarization filter 622 through the driving member 640. Since the transmissive axis is rotated according to the rotation of polarization filter 622, the oscillating direction of light that can pass through polarization filter 622 may be changed.

The controller 70 may receive data from the photosensitive sensor 600. The controller 70 may detect light emitted inside the chamber 10 by processing the data received from the photosensitive sensor 600. The controller 70 may detect the status of plasma inside the chamber 10 by processing the data received from the photosensitive sensor 600.

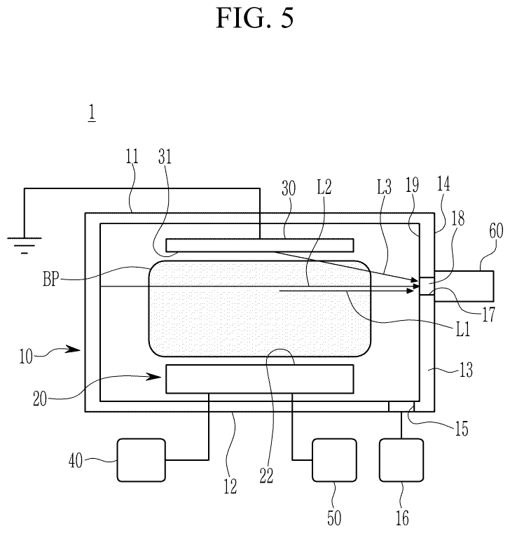

FIG. 5 is a drawing illustrating light incident to a detection module 60 through the measurement window 17 of a substrate processing apparatus 1 according to some embodiments.

Referring to FIG. 5, lights propagating from various positions toward the measurement window 17 may be incident to the detection module 60.

First, light L1 emitted from the bulk plasma BP may be incident to the detection module 60 through the measurement window 17. As described above, the process gas inserted into the chamber 10 is excited into plasma by the electric field, and may generate bulk plasma BP. At this time, the bulk plasma BP is in a state where the process gas is divided into particles such as electrons, neutral particles, and ions, and may be electrically neutral because the numbers of negative and positive charges are equal. The bulk plasma BP may be surrounded by a plasma sheath. Additionally, the bulk plasma BP may emit light. The light L1 emitted from such bulk plasma BP may be incident to the detection module 60 through the measurement window 17.

Also, light L2 reflected from the inner surface 19 of the chamber 10 may be incident to the detection module 60 through the measurement window 17. Depending on the condition of the inner surface 19 of the chamber 10, the amount or intensity of light L2 reflected from the inner surface 19 of the chamber 10 may be changed. For example, the inner surface 19 of the chamber 10 may be made of material having anti-corrosion properties against plasma, such as yttrium oxide Y2O3.

Additionally, light L3 emitted from the plasma excitation member 30 may be incident to the detection module 60 through the measurement window 17. Particularly, light L3 emitted from the lower surface 31 of the plasma excitation member 30 may be incident to the detection module 60. Plasma adjacent to the plasma excitation member 30 may be incident to the plasma excitation member 30. For example, electrons contained in the plasma may be incident to the plasma excitation member 30, and cathodoluminescence may occur on the lower surface 31 of the plasma excitation member 30. In this way, the light L3 emitted from the lower surface 31 of the plasma excitation member 30 may be incident to the detection module 60. Since the lower surface 31 of the plasma excitation member 30 is positioned to face the bulk plasma BP, the cathodoluminescence may be mostly generated on the lower surface 31 of the plasma excitation member 30.

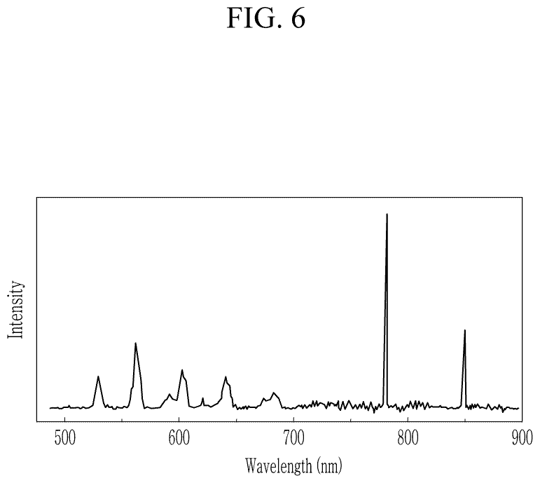

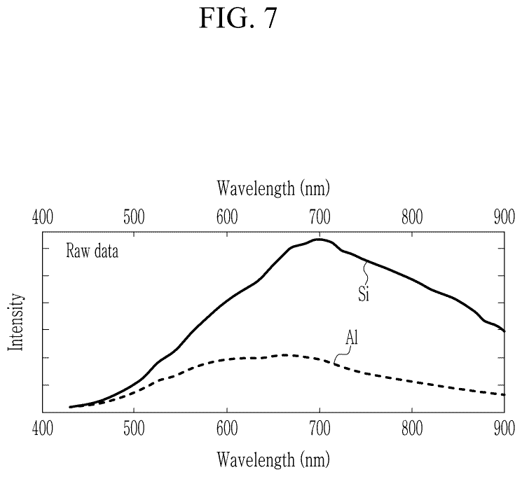

FIG. 6 is a drawing illustrating a wavelength spectrum of light L1 radiated from bulk plasma BP. FIG. 7 is a drawing illustrating a wavelength spectrum of light emitted by cathodoluminescence.

Referring to FIG. 6 to FIG. 7, the wavelength spectrum of the light L1 emitted from bulk plasma BP exhibits a peak value in a specific wavelength band, and the intensity rapidly decreases at a front and back of the specific wavelength band of the peak value. That is, the wavelength spectrum of the light L1 emitted from bulk plasma BP sharply increases in a pulse form in a specific wavelength band and exhibits a significantly lower intensity in other wavelength bands than in the specific wavelength band. Additionally, in the wavelength spectrum of the light L1 emitted from bulk plasma BP, the specific wavelength band that exhibit significantly higher intensities than other wavelength bands may be plural. Additionally, the wavelength spectrum of light L1 emitted from bulk plasma BP may vary depending on type of the process gas used to excite the plasma. That is, in the wavelength spectrum of light L1 radiated from bulk plasma BP, the specific wavelength band exhibiting a significantly higher intensity than the other wavelength bands may vary depending on type of the process gas. FIG. 6 illustrates a wavelength spectrum when oxygen is used as a process gas.

Additionally, the wavelength spectrum of light L2 reflected from a inner surface of the chamber 10 may correspond to the wavelength spectrum of light L1 emitted from bulk plasma BP. That is, most of the light incident to a inner surface of the chamber 10 may be light emitted from the bulk plasma BP. Therefore, the wavelength spectrum of light L2 reflected from a inner surface of the chamber 10 may have a shape corresponding to the wavelength spectrum of light L1 emitted from bulk plasma BP. Also, the intensity of the light L2 reflected from a inner surface of the chamber 10 may vary depending on material of the inner surface of the chamber 10. For example, when a inner surface of the chamber 10 is made of material such as oxidationyttrium (Y2O3) as described above, the amount or intensity of the light reflected from the inner surface of the chamber 10 may be increased.

On the other hand, the wavelength spectrum of light emitted by cathodoluminescence exhibits a peak value at a specific wavelength, and the intensity gradually decreases at a front and back of the specific wavelength of the peak value. That is, the light L1 emitted from bulk plasma BP exhibits a sharp change in intensity between the wavelength band where the intensity increases rapidly and the other wavelength bands. On the other hand, in the wavelength spectrum of light emitted by cathodoluminescence, intensity change gradually occurs depending on wavelength changes. Additionally, the wavelength spectrum of light emitted by cathodoluminescence varies depending on the type of material generating cathodoluminescence. The wavelength spectrum depicted in FIG. 7 is a wavelength spectrum of cathodoluminescence of Si and Al.

As described above, cathodoluminescence may occur at a lower surface 31 of the plasma excitation member 30. Accordingly, the wavelength spectrum of the light L3 emitted from the lower surface 31 of the plasma excitation member 30 may exhibit a peak value at a specific wavelength, and the intensity may gradually decrease at a front and back of the specific wavelength having the peak value. In other words, the intensity of the light L3 emitted from the lower surface 31 of the plasma excitation member 30 may gradually decrease as the wavelength increases from the specific wavelength and may gradually decrease as the wavelength decreases from the specific wavelength.

Accordingly, the filter 620 can selectively allow light used for measuring the internal state of the chamber 10, among the light incident through measurement window 17, to be incident on the photosensitive sensor 600. Specifically, the wavelength filter 621 may filter the light L1 emitted from the bulk plasma BP. The wavelength filter 621 may be provided to filter a wavelength band whose intensity exhibits a peak value in the wavelength spectrum of the light L1 emitted from the bulk plasma BP. For example, the wavelength filter 621 may be provided to filter a wavelength band whose intensity exhibits a peak value in the wavelength spectrum of the light L1 emitted from the bulk plasma BP corresponding to the type of process gas used for plasma excitation.

Accordingly, when light incident through measurement window 17 passes through the wavelength filter 621, most of the light L1 emitted from the bulk plasma BP may be filtered. Additionally, when the light incident through the measurement window 17 passes through the wavelength filter 621, most of the light L2 reflected from a inner surface of the chamber 10 may be filtered.

Additionally, the wavelength filter 621 may be provided in plural. A plurality of wavelength filters 621 may be in series along the propagation path of light. Therefore, the light incident through the measurement window 17 may sequentially pass through each of the wavelength filters 621. When the wavelength filters 621 are provided in plural, the polarization filter 622 may be in front of the wavelength filter 621. Additionally, when the wavelength filters 621 are provided in plural, the polarization filter 622 may be behind the wavelength filters 621. Also, when the wavelength filters 621 are provided in plural, the polarization filter 622 may be between two wavelength filters 621.

As described above, in the wavelength spectrum of light L1 emitted from bulk plasma BP, the specific wavelength band that exhibit significantly higher intensities than the other wavelength bands may be plural. A plurality of wavelength filters may be provided corresponding to those specific wavelength bands, and each of the wavelength filters 621 may filter at least one wavelength band among specific wavelength bands that exhibit intensity significantly higher than the other wavelength bands in the wavelength spectrum of the light L1 emitted from the bulk plasma BP.

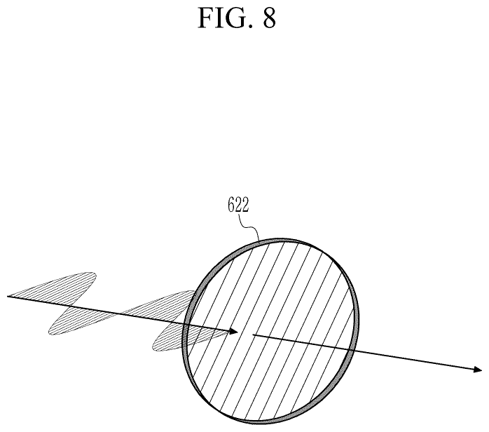

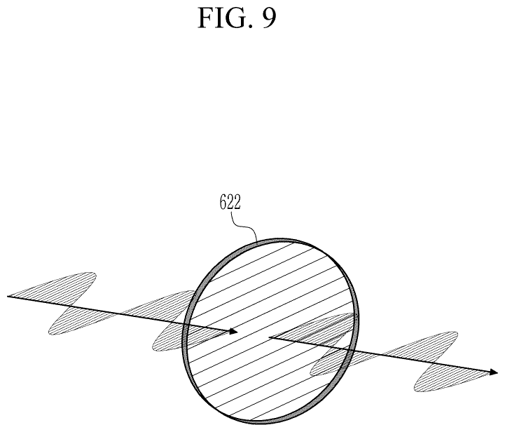

FIG. 8 is a drawing illustrating a state of a polarization filter 622 wherein light oscillating in a direction and incident through the measurement window 17 is filtered by the polarization filter 622 according to some embodiments. FIG. 9 is a drawing illustrating a state of a polarization filter 622 wherein light oscillating in a direction and incident through the measurement window 17 passes through the polarization filter 622 according to some embodiments.

Referring to FIG. 8 to FIG. 9, when light is incident through the measurement window 17, the polarization filter 622 may be rotated. That is, light oscillating in a direction may be filtered by the polarization filter 622 when the polarization filter 622 is in a state as shown in FIG. 8. Additionally, when the polarization filter 622 is rotated and in a state as shown in FIG. 9, light oscillating in a direction may pass through the polarization filter 622.

Light incident through measurement window 17 may include light having a polarized characteristic. Specifically, light emitted by cathodoluminescence may exhibit polarized characteristics. Accordingly, the light L3 emitted from the lower surface 31 of the plasma excitation member 30 may exhibit polarized characteristics. On the other hand, the light L1 emitted from the bulk plasma BP does not exhibit polarized characteristics. Accordingly, when light is incident through the measurement window 17, the controller 70 may rotate the polarization filter 622 by activating the driving member 640 at least once. As shown in FIG. 8, when the polarization filter 622 is in a state wherein the transmissive axis of the polarization filter 622 intersects the oscillating direction of the light L3 emitted from the plasma excitation member 30, the light L3 emitted from the plasma excitation member 30 is filtered out by the polarization filter 622. On the other hand, as shown in FIG. 9, when the transmissive axis of the polarization filter 622 is parallel to the oscillating direction of the light L3 emitted from the plasma excitation member 30, the light L3 emitted from the plasma excitation member 30 may pass through the polarization filter 622. When the light L3 emitted from plasma excitation member 30 passes through the polarization filter 622, the intensity of the light detected by the photosensitive sensor 600 increases more than when it is filtered by the polarization filter 622. Accordingly, through the intensity of light detected by the photosensitive sensor 600, the controller 70 may detect whether the data received from the photosensitive sensor 600 is measured when light L3 emitted from the plasma excitation member 30 is filtered by the polarization filter 622 or when light L3 emitted from the plasma excitation member 30 passes through the polarization filter 622. Specifically, when an intensity increasing point at which the intensity of light detected by the photosensitive sensor 600 increases occurs during rotating the polarization filter 622, the controller 70 may determine that the light measured by the photosensitive sensor 600 at the intensity increasing point includes the light L3 emitted from the plasma excitation member 30. Additionally, the controller 70 may determine that the light measured by the photosensitive sensor 600 at a time other than the intensity increasing point does not include the light L3 emitted from the plasma excitation member 30.

The controller 70 may extract data measuring the light L3 emitted from plasma excitation member 30, through the difference between data received from the photosensitive sensor 600 at the intensity increasing point and data received from the photosensitive sensor 600 at times other than the intensity increasing point. Specifically, the controller 70 may extract data measuring the light L3 emitted from plasma excitation member 30, through an operation of subtracting the data received from the photosensitive sensor 600 at a time other than the intensity increasing point from the data received from the photosensitive sensor 600 at the intensity increasing point. In other words, the controller 70 may be configured to perform an operation wherein the data received from the photosensitive sensor 600 at a time other than the intensity increasing point is subtracted from the data received from the photosensitive sensor 600 at the intensity increasing point.

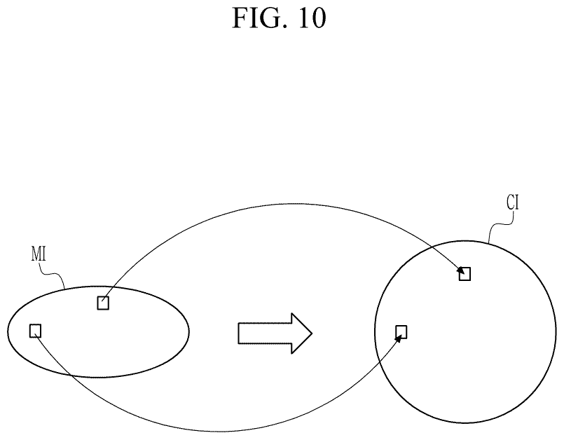

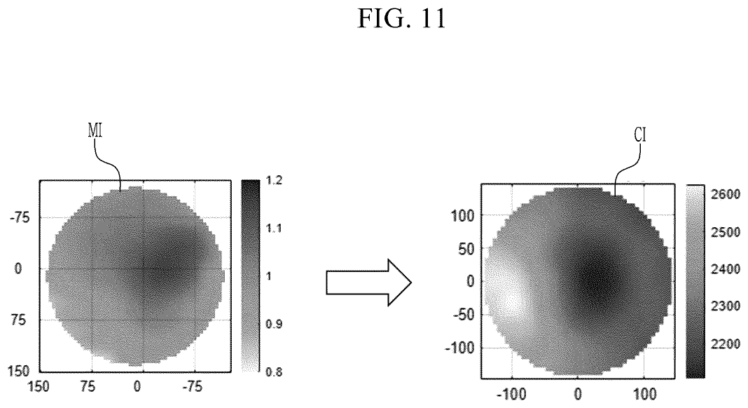

FIG. 10 and FIG. 11 are drawings illustrating a process of converting a measurement image MI measured by a detection module 60 into a compensated image CI representing the light L3 emitted from the lower surface 31 of the plasma excitation member 30 according to some embodiments. FIG. 10 is a drawing illustrating a state where coordinate compensation is performed. FIG. 11 is a drawing illustrating a state where brightness compensation is performed.

Hereinafter, the process of converting the measured data from the detection module 60 into data representing the light L3 emitted from the lower surface 31 of the plasma excitation member 30 will be described with reference to FIG. 10 and FIG. 11.

The light L3 emitted from the plasma excitation member 30 propagates toward the detection module 60 in a direction oblique to the vertical direction and horizontal direction. Accordingly, when the light L3 emitted from the lower surface 31 of plasma excitation member 30 is incident to the photosensitive sensor 600 of the detection module 60, the lower surface 31 of the plasma excitation member 30 may have an elliptical shape as the measurement image MI, as shown at the left side of FIG. 10. Accordingly, the controller 70 may correct the elliptical measurement image MI measured by the photosensitive sensor 600 of the detection module 60 into a circle corresponding to the actual shape of the lower surface 31 of the plasma excitation member 30. For example, the controller 70 may obtain a compensated image CI, by performing a compensation operation of multiplying the measurement image MI data received from the photosensitive sensor 600 of the detection module 60 by the coordinate compensation value T1, as in equation 1 below. In other words, the controller 70 may be configured to perform an operation wherein the measurement image MI data received from the photosensitive sensor 600 of the detection module 60 is multiplied by the coordinate compensation value T1 to obtain compensated image CI data. This operation may convert a measurement image MI measured by the detection module 60 into a compensated image CI which represents the light emitted from the plasma excitation member 30. In equation 1, (x′, y′, z′) is the measurement image MI data, T1 is the coordinate compensation value, and (x, y, z) is the compensated image CI data with the coordinates compensated. The coordinate compensation value T1 may be derived from a geometric co-relationship or optical co-relationship transforming an ellipse into a circle. The coordinate compensation value may be a transformation matrix transforming an ellipse into a circle.

$$( x , y , z ) = T 1 \times ( {x}^{′} , {y}^{′} , {z}^{′} ) \qquad [ equation 1 ]$$

There may be a deviation between the actual light emitted from the plasma excitation member 30 and the light detected by the photosensitive sensor 600 of the detection module 60. Specifically, a part of the light L3 emitted from plasma excitation member 30 is incident to the photosensitive sensor 600 of the detection module 60 through the measurement window 17. Additionally, a part of wavelength bands of the light L3 emitted from the plasma excitation member 30 may be filtered by the wavelength filter 621 and may not be measured by the photosensitive sensor 600 of the detection module 60. Therefore, it is necessary to compensate the brightness of the measurement image MI measured by the photosensitive sensor 600 of the detection module 60 shown at the left of FIG. 11 to the brightness of the lower surface 31 of the plasma excitation member 30 shown at the right of FIG. 11. Accordingly, the controller 70 may perform a compensation operation of multiplying the measurement image MI including the brightness value measured by the photosensitive sensor 600 by the brightness compensation value T2, as in equation 2, to obtain the compensated image CI including the brightness value. In other words, the controller 70 may be configured to perform an operation wherein the measurement image MI including the brightness value measured by the photosensitive sensor 600 is multiplied by the brightness compensation value T2, as in equation 2, to obtain the compensated image CI including the brightness value. In equation 2, I′(x′, y′, z′) is the measurement image MI data containing the brightness value, T2 is a brightness compensation value, and I(x,y,z) is the compensated image CI data containing the brightness value. The brightness compensation value T2 may be a value derived from an optical co-relationship. Additionally, the brightness compensation value T2 may be a derived value that represents the co-relationship between the measurement image MI and the compensated image CI through experiments. The brightness compensation value T2 can be a transformation matrix.

$$I ( x , y , z ) = T 2 \times {I}^{′} ( {x}^{′} , {y}^{′} , {z}^{′} ) \qquad [ equation 2 ]$$

The operation using equation 1 and the operation using equation 2 may be performed sequentially. For example, the operation using equation 2 may be performed after the operation using equation 1. Alternatively, the operation using equation 1 may be performed after the operation using equation 2. Also, the operation using equation 1 and the operation using equation 2 may be performed together. That is, the measurement image MI data may include coordinate data and the brightness value of each coordinate. Additionally, by performing an operation of multiplying the measurement image MI data by the coordinate compensation value T1 and the brightness compensation value T2, the controller 70 may obtain the compensated image CI data with the coordinate and brightness values corrected. In other words, the controller 70 may be configured to perform an operation wherein the measurement image MI data is multiplied by the coordinate compensation value T1 and the brightness compensation value T2 to obtain the compensated image CI data with the coordinate and brightness values corrected.

A substrate processing apparatus 1 according to some embodiments may detect the state of plasma through light emitted inside the chamber 10. Specifically, the substrate processing apparatus 1 according to some embodiments may detect light emitted from the lower surface 31 of the plasma excitation member 30. The detection module 60 may be spaced more downwardly than and apart from the lower surface 31 of the plasma excitation member 30 by an offset distance OF. The lens 610 may be spaced more downwardly than and apart from the lower surface 31 of plasma excitation member 30 by an offset distance OF. A center of the lens 610 may be spaced more downwardly than and apart from the lower surface 31 of plasma excitation member 30 by an offset distance OF. Accordingly, light emitted from the lower surface 31 of plasma excitation member 30 may be incident to the lens 610 in a direction intersecting the vertical direction and horizontal direction, and then may be incident to the photosensitive sensor 600. Accordingly, even when one measurement window 17 and one detection module 60 are at a side of the chamber 10, a two-dimensional measurement image MI may be obtained through the photosensitive sensor 600.

Also, the light L3 emitted from the lower surface 31 of plasma excitation member 30 is generated by the plasma. That is, the state of the light L3 emitted from the lower surface 31 of the plasma excitation member 30 may reflect the state of the plasma. Accordingly, the plasma state inside the chamber 10 may be detected through the brightness of the lower surface 31 of the plasma excitation member 30. In addition, since the measurement image MI and compensated image CI are acquired in a two-dimensional form, the plasma state of the region positioned below the plasma excitation member 30 may be effectively detected.

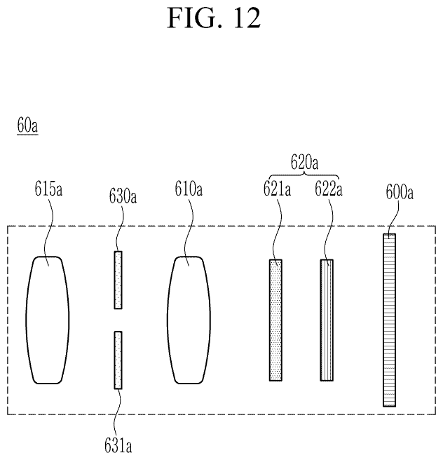

FIG. 12 is a drawing illustrating a detection module 60a according to some embodiments.

Referring to FIG. 12, the detection module 60a may include a photosensitive sensor 600a, a lens 610a, an auxiliary lens 615a and a filter 620a.

The auxiliary lens 615a may be on the path of light generated inside the chamber 10 and passing through the measurement window 17. The lens 610 auxiliary lens 615a may be spaced downwardly apart from the lower surface 31 of plasma excitation member 30 by an offset distance OF. A center of the auxiliary lens 615a may be spaced downwardly apart from the lower surface 31 of plasma excitation member 30 by an offset distance OF. The offset distance OF has a value greater than 0. Additionally, the offset distance OF may be 5 mm or more. The offset distance OF may be 10 mm or more. Accordingly, light L3 emitted from the lower surface 31 of plasma excitation member 30 may propagate in a direction oblique to vertical direction and horizontal direction, and may enter the auxiliary lens 615a.

The auxiliary lens 615a may be in front of the photosensitive sensor 600a, in reference to the propagation path of light. The auxiliary lens 615a may be between the photosensitive sensor 600a and the internal space of the chamber 10. The auxiliary lens 615a may be behind shield member 18. The auxiliary lens 615a may be between the shield member 18 and the photosensitive sensor 600.

For example, the auxiliary lens 615a may be behind further than the outer surface 14 of the side wall 13 of the chamber 10. That is, the auxiliary lens 615a may be outside the chamber 10. Additionally, at least a portion of the detection module 60a may be inserted into the measurement window 17 from the outer surface 14 of the side wall 13 of the chamber 10 toward the inner surface 19 of the side wall 13 of the chamber 10. Additionally, the auxiliary lens 615a may be inserted into the measurement window 17 and positioned in a section between the inner surface 19 of the side wall 13 of the chamber 10 and the outer surface 14 of the side wall 13 of the chamber 10.

The auxiliary lens 615a may control the propagation direction of light incident from the front which is toward the inside of the chamber 10. For example, light incident from the front may become a parallel beam after passing through the auxiliary lens 615a.

That is, the auxiliary lens 615a may be in front of the lens 610a. The auxiliary lens 615a may be in front of the entrance plate 630a. The entrance plate 630a may be between the auxiliary lens 615a and the lens 610a. A pin hole 631a may be positioned on the entrance plate 630a.

The filter 620a may include a wavelength filter 621a and a polarization filter 622a.

Others, such as the structure of the photosensitive sensor 600a, lens 610a, entrance plate 630a and filter 620a and the control process by the controller 70, are the same or similar to the detection module 60 described above in FIG. 1 to FIG. 11, so repeated descriptions are omitted.

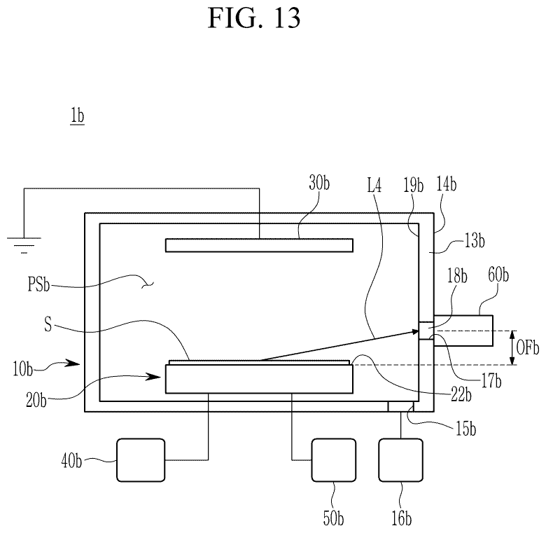

FIG. 13 is a drawing illustrating a substrate processing apparatus 1b according to some embodiments.

Referring to FIG. 13, a substrate processing apparatus 1b according to some embodiments may include a chamber 10b, a support member 20b, a plasma excitation member 30b, an excitation supply unit 40b, a bias supply unit 50b, and a detection module 60b.

The chamber 10b provides a processing space PSb where the substrate treatment process is performed inside. An exhaust hole 15b may be positioned in a side of the chamber 10b. The discharge member 16b may be connected to the exhaust hole 15b. The measurement window 17b may be positioned in a side of the chamber 10b. The measurement window 17b may be positioned in a side wall 13b of the chamber 10b. The measurement window 17b may penetrate the inner and outer surfaces of the chamber 10b and thereby provide a path for light generated inside the chamber 10b to propagate to the outside of the chamber 10b. A shield member 18b may be inside of or adjacent to the measurement window 17b. The other configurations of the chamber 10b are same or similar to the chamber 10 of FIG. 1, so repeated descriptions are omitted.

The detection module 60b may detect light emitted inside the chamber 10b. The detection module 60b may detect light emitted from the support member 20b. The detection module 60b may detect light emitted from the substrate S positioned on the support member 20b during the substrate processing process.

The detection module 60b may face the measurement window 17b and may detect light incident through the measurement window 17b.

The detection module 60b may be spaced upwardly apart from the upper surface 22b of the support member 20b by an offset distance OFb. The offset distance OFb has a value greater than 0. The offset distance OFb may be 5 mm or more. Additionally, the offset distance OFb may be 10 mm or more. Accordingly, the light L4 emitted from the upper surface of the substrate S positioned on the support member 20b propagates in a direction oblique to the vertical direction and the horizontal direction and may be incident to the detection module 60b.

The detection module 60b may be outside the processing space PSb. As an example, the detection module 60b may be provided connected to a region, where a measurement window 17b is positioned, of the outer surface 14b of the side wall 13b of the chamber 10b. Additionally, at least a portion of the detection module 60b may be inside the measurement window 17b. That is, at least a portion of the detection module 60b may be inserted at the outer surface 14b of the side wall 13b of the chamber 10b toward the inner surface 19b of the side wall 13b of the chamber 10b. Also, the detection module 60b may be apart from the outer surface 14b of the side wall 13b of the chamber 10b to face the measurement window 17b. FIG. 13 illustrate an example where the detection module 60b may be connected to the side wall 13b of the chamber 10b.

The detection module 60b may filter light reflected from the bulk plasma BP and a inner surface of the chamber 10b, among the light incident through the measurement window 17b, in the same or similar manner as described above in FIG. 5 to FIG. 9.

Additionally, the detection module 60b may filter light emitted from the plasma excitation member 30b, among the light incident through the measurement window 17b, in the same or similar manner as described above in FIG. 5 to FIG. 9.

The structure of the detection module 60b is the same or similar to that of the detection module 60 described in FIG. 4 or the detection module 60a described in FIG. 12, so repeated descriptions are omitted.

The controller 70 may detect the status of plasma inside the chamber 10b by processing the data received from the detection module 60b.

In addition, the other structures of the substrate processing apparatus 1b are the same or similar to what described above in FIG. 1 to FIG. 11, so repeated descriptions are omitted.

In addition, the processes that the controller 70 controls the components of the substrate processing apparatus 1b and processes the data received from the detection module 60b are the same or similar what described above in FIG. 1 to FIG. 11, so repeated descriptions are omitted.

A substrate processing apparatus 1b according to some embodiments may detect the state of plasma through light emitted inside the chamber 10b. Specifically, the substrate processing apparatus 1b according to some embodiments may detect light emitted from the substrate S. Specifically, during processing the substrate, the material of the substrate S reacts with plasma, and then light may be generated. That is, the state of light generated from the substrate S during processing the substrate S may reflect the state of the plasma. Accordingly, the plasma state inside the chamber 10b may be detected through the light L4 emitted from the substrate S.

The detection module 60b may be spaced more upwardly than and apart from the upper surface 22b of the support member 20b by an offset distance OFb. When the detection module 60b has a structure identical to or similar to the detection module 60 of FIG. 3, the lens may be spaced more upwardly than and apart from the support member 20b by an offset distance OFb. A center of the lens may be spaced more upwardly than and apart from the upper surface 22b of the support member 20b by an offset distance OFb. Also, when the detection module 60b has a structure identical to or similar to the detection module 60 of FIG. 12, the lens may be spaced more upwardly than and apart from the support member 20b by an offset distance OFb. A center of the auxiliary lens may be spaced more upwardly than and apart from the upper surface 22b of the support member 20b by an offset distance OFb. Accordingly, the light L4 emitted from the upper surface of the substrate S may be incident to the detection module 60b in a direction intersecting the vertical direction and the horizontal direction. Accordingly, even when one measurement window 17b and one detection module 60b are at a side of the chamber 10b, a two-dimensional measurement image MI may be obtained. In addition, since the measurement image MI and the compensated image CI obtained from the measurement image MI are in two-dimensional form, the plasma state of a region positioned above the substrate S may be effectively detected.

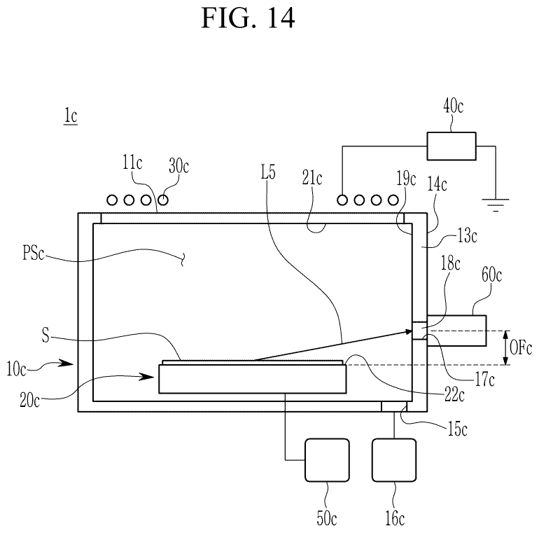

FIG. 14 is a drawing illustrating a substrate processing apparatus 1c according to some embodiments.

Referring to FIG. 14, a substrate processing apparatus 1c according to some embodiments may include a chamber 10c, a support member 20c, a plasma excitation member 30c, an excitation supply unit 40c, a bias supply unit 50c, and a detection module 60c.

The chamber 10c provides a processing space PSc where the substrate treatment process is performed inside. At least a portion of the upper wall 11c of the chamber 10c may be made of dielectric material. An exhaust hole 15c may be positioned in a side of the chamber 10c. The discharge member 16c may be connected to the exhaust hole 15c. The measurement window 17c may be positioned in a side of the chamber 10c. The measurement window 17c may be positioned in a side wall 13c of the chamber 10c. The measurement window 17c may penetrate the inner and outer surfaces of the chamber 10c and thereby provide a path for light generated inside the chamber 10c to propagate to the outside of the chamber 10c. A shield member 18c may be in the measurement window 17c. The other configurations of the chamber 10c are same or similar to the chamber 10 of FIG. 1, so repeated descriptions are omitted.

The plasma excitation member 30c applies energy for plasma excitation inside the chamber 10c. The plasma excitation member 30c may have an antenna structure. The plasma excitation member 30c is inside the chamber 10c. The plasma excitation member 30 may be adjacent to an upper surface 21c of the upper wall 11c of the chamber 10c. The plasma excitation member 30c may face the internal space of the chamber 10c with the upper wall 11c of the chamber 10c interposed therebetween.

The excitation supply unit 40c provides electric power for plasma excitation. The excitation supply unit 40c may be electrically connected to the plasma excitation member 30c. The excitation supply unit 40c may include a high-frequency power source generating high-frequency electric power. The excitation supply unit 40c may include RF power. The plasma excitation member 30c generates electromagnetic waves through the electric power provided by the excitation supply unit 40c. The gas supplied inside the chamber 10c may be excited into plasma by the electromagnetic wave generated in plasma excitation member 30c.

The detection module 60c may detect light emitted inside the chamber 10c. The detection module 60c may detect light emitted from the support member 20c. The detection module 60c may detect light L5 emitted from the substrate S positioned on the support member 20c during the substrate processing process. The detection module 60c may face the measurement window 17c and may detect light incident through the measurement window 17c. The detection module 60c may be spaced upwardly apart from the upper surface 22c of the support member 20c by an offset distance OFc. The offset distance OFc has a value greater than 0. The offset distance OFc may be 5 mm or more. The offset distance OFc may be 10 mm or more. Accordingly, the light L5 emitted from the upper surface of the substrate S positioned on the support member 20c propagates in a direction oblique to the vertical direction and the horizontal direction and may be incident to the detection module 60c.

The detection module 60c may be outside the processing space PS. As an example, the detection module 60c may be provided connected to a region, where a measurement window 17c is positioned, of the outer surface 14c of the side wall 13c of the chamber 10c. Additionally, at least a portion of the detection module 60c may be positioned inside the measurement window 17c. That is, at least a portion of the detection module 60c may be inserted at the outer surface 14c of the side wall 13c of the chamber 10c toward the inner surface 19c of the side wall 13c of the chamber 10c. Also, the detection module 60c may be apart from the outer surface 14c of the side wall 13c of the chamber 10c to face the measurement window 17c. FIG. 13 illustrate an example where the detection module 60c is connected to the side wall 13c of the chamber 10c.

The detection module 60c may filter light reflected from the bulk plasma BP and the inner surface 19c of the chamber 10c, among the light incident through the measurement window 17c, in the same or similar manner as described above in FIG. 5 to FIG. 9.

The structure of the detection module 60c is the same or similar to that of the detection module 60 described in FIG. 4 or the detection module 60a described in FIG. 12, so repeated descriptions are omitted.

The controller 70 may detect the status of plasma inside the chamber 10c by processing the data received from the detection module 60c.

In addition, the other structures of the substrate processing apparatus 1c are the same or similar to what described above in FIG. 1 to FIG. 11, so repeated descriptions are omitted.

In addition, the processes that the controller 70 controls the components of the substrate processing apparatus 1c and processes the data received from the detection module 60c are the same or similar what described above in FIG. 1 to FIG. 11, so repeated descriptions are omitted.

A substrate processing apparatus 1c according to some embodiments may detect the state of plasma through light emitted inside the chamber 10c. Specifically, the substrate processing apparatus 1c according to some embodiments may detect light L5 emitted from the substrate S. Specifically, during processing the substrate S, the material of the substrate S reacts with plasma, and then light may be generated. That is, the state of light L5 generated from the substrate S during processing the substrate S may reflect the state of the plasma. Accordingly, the plasma state inside the chamber 10c may be detected through the light L5 emitted from the substrate S.

The detection module 60c may be spaced more upwardly than and apart from the upper surface 22c of the support member 20c by an offset distance OFc. When the detection module 60c has a structure identical to or similar to the detection module 60 of FIG. 3, the lens may be spaced more upwardly than and apart from the support member 20c by an offset distance OFc. A center of the lens may be spaced more upwardly than and apart from the upper surface 22c of the support member 20c by an offset distance OFc. Also, when the detection module 60c has a structure identical to or similar to the detection module 60 of FIG. 12, the lens may be spaced more upwardly than and apart from the support member 20c by an offset distance OFc. A center of the auxiliary lens may be spaced more upwardly than and apart from the upper surface 22c of the support member 20c by an offset distance OFc. Accordingly, the light L5 emitted from the upper surface of the substrate S may be incident to the detection module 60c in a direction intersecting the vertical direction and the horizontal direction. Accordingly, even when one measurement window 17c and one detection module 60c are at a side of the chamber 10c, a two-dimensional measurement image MI may be obtained. In addition, since the measurement image MI and the compensated image CI obtained from the measurement image MI are in two-dimensional form, the plasma state of a region positioned above the substrate S may be effectively detected.

Although some embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

What is claimed is:

1. A substrate processing apparatus comprising:
a chamber including a measurement window in a side of the chamber and configured to provide a path for light to propagate;
a plasma excitation member configured to apply energy for excitation of plasma in the chamber;
a support member inside of the chamber and configured to support a substrate; and
a detection module positioned to face the measurement window, and configured to detect light emitted from the plasma excitation member through the measurement window.

2. The substrate processing apparatus of claim 1, wherein
the measurement window is in a side wall of the chamber.

3. The substrate processing apparatus of claim 2, wherein
the detection module is spaced downwardly apart from a lower surface of the plasma excitation member by an offset distance.

4. The substrate processing apparatus of claim 3, wherein
the offset distance is 5 mm or more.

5. The substrate processing apparatus of claim 1, wherein
the detection module comprises:
a photosensitive sensor;
a lens configured to refract incident light and to propagate the incident light toward the photosensitive sensor; and
a filter between the photosensitive sensor and the lens.

6. The substrate processing apparatus of claim 5, wherein
the filter comprises a wavelength filter configured to filter a wavelength band whose intensity exhibits a peak value at a wavelength spectrum of bulk plasma excited inside the chamber.

7. The substrate processing apparatus of claim 5, wherein
the filter comprises a polarization filter.

8. The substrate processing apparatus of claim 7, further comprising
a driving member connected to the polarization filter and configured to rotate the polarization filter.

9. The substrate processing apparatus of claim 5, wherein
a center of the lens is spaced downwardly apart from a lower surface of the plasma excitation member by an offset distance.

10. The substrate processing apparatus of claim 1, further comprising a controller configured to perform an operation wherein a measurement image measured by the detection module is converted into a compensation image which represents the light emitted from the plasma excitation member.

11. The substrate processing apparatus of claim 10, wherein
the controller is configured to perform the operation wherein the measurement image has an elliptical shape and is multiplied by a coordinate compensation value to obtain the compensated image, the compensated image having a circular shape.

12. The substrate processing apparatus of claim 10, wherein
the controller is configured to perform the operation wherein the measurement image including a brightness value is multiplied by a brightness compensation value to obtain the compensated image including a brightness value.

13. A substrate processing apparatus comprising:
a chamber including a measurement window in a side of the chamber and configured to provide a path for light to propagate;
a plasma excitation member configured to apply energy for excitation of plasma in the chamber;
a support member inside of the chamber and configured to support a substrate; and
a detection module positioned to face the measurement window, and configured to detect light emitted from a substrate positioned on the support member through the measurement window when the substrate is being processed.

14. The substrate processing apparatus of claim 13, wherein
the measurement window is in a side wall of the chamber.

15. The substrate processing apparatus of claim 14, wherein
the detection module is spaced upwardly apart from an upper surface of the support member by an offset distance.

16. The substrate processing apparatus of claim 13, wherein
the detection module comprises:
a photosensitive sensor;
a lens configured to refract incident light to propagate the incident light toward the photosensitive sensor; and
a filter between the photosensitive sensor and the lens.

17. A substrate processing apparatus comprising:
a chamber including a measurement window in a side of the chamber and configured to provide a path for light to propagate;
a plasma excitation member configured to apply energy for excitation of plasma in the chamber;
a support member inside of the chamber and configured to support a substrate; and
a detection module positioned to face the measurement window, and configured to detect light emitted from the plasma excitation member through the measurement window, wherein:
the detection module comprises:
a photosensitive sensor;
a lens configured to refract incident light to propagate the incident light toward the photosensitive sensor; and
a wavelength filter between the photosensitive sensor and the lens and configured to filter a wavelength band whose intensity exhibits a peak value at a wavelength spectrum of bulk plasma excited inside the chamber.

18. The substrate processing apparatus of claim 17, wherein:
the measurement window is in a side wall of the chamber; and
the detection module is spaced downwardly apart from a lower surface of the plasma excitation member by an offset distance.

19. The substrate processing apparatus of claim 17, further comprising
a controller configured to perform an operation wherein a measurement image measured by the photosensitive sensor is converted into a compensation image which represents the light emitted from the plasma excitation member.

20. The substrate processing apparatus of claim 17, wherein
the detection module further comprises
a polarization filter between the photosensitive sensor and the lens.
